(19) United States
(12) Patent Application Publication
(10) Pub. No.: US 2025/0132741 A1
(43) Pub. Date: Apr. 24, 2025

(54) AMPLIFICATION CIRCUIT

(71) Applicant: RichWave Technology Corp, Taipei City (TW)

(72) Inventors: Tien-Yun Peng, Taipei City (TW); Chih-Sheng Chen, Taipei City (TW)

(73) Assignee: RichWave Technology Corp, Taipei City (TW)

(21) Appl. No.: 18/389,719

(22) Filed: Dec. 19, 2023

(30) Foreign Application Priority Data
Oct. 18, 2023 (TW) 112139718

(51) Int. Cl. H03F 3/45

(52) U.S. Cl. CPC H03F 3/45475

(57) ABSTRACT

An amplification circuit includes an amplifier, a first mirror-branch circuit, a second mirror-branch circuit, a first variable current source, a second variable current source, and an operation amplifier. The amplifier can receive an operation current and an input signal, and output the amplified input signal. The first mirror-branch circuit and the second mirror-branch circuit are coupled to the amplifier. The first variable current source is coupled to the first mirror-branch circuit and provides a first reference current. The second variable current source is coupled to the second mirror-branch circuit and provides a second reference current. The operation amplifier is coupled to the first mirror-branch circuit, the second mirror-branch circuit and the amplifier. The first reference current and the second reference current are related to the operation current.

### TECHNICAL FIELD

The disclosure is related to an amplification circuit, and more particularly, an amplification circuit including a variable current source.

### BACKGROUND

Current mirrors are basic circuit structures of analog circuits and are widely used for loads of various bias circuits and amplification devices. Hence, the accuracy of mirroring characteristics of a current mirror is important. The stability and accuracy of an output current of a current mirror can determine the quality of the characteristics of the current mirror.

Currently, metal-oxide-semiconductor field effect transistors (MOSFETs) are often used in a current mirror circuit. When an MOSFET is operated in a linear region, its effective channel length will be fixed. However, when a drain bias voltage of the MOSFET is increased to enter a saturation region, the channel length will be shortened. Hence, the relationship between the operation current and voltage in the saturation region is no longer ideal to be only related to a gate-source voltage (VGS) of the transistor, and is also related to a drain-source voltage (VDS) due to the channel length modulation effect. Therefore, the mirror current of the amplification circuit is easily affected by changes of the manufacturing process and a bias voltage of the MOSFET. In addition, since the current value of the amplification circuit is difficult to be adjusted, a solution to improve the controllability of the current amplification circuit is still in need.

### SUMMARY

An embodiment provides an amplification circuit comprising an amplifier, a first mirror-branch circuit, a second mirror-branch circuit, a first variable current source, a second variable current source, and an operational amplifier. The amplifier is configured to receive an operation current and includes a first terminal configured to receive an input signal, and a second terminal configured to output an amplified input signal. The first mirror-branch circuit is coupled to the amplifier. The second mirror-branch circuit is coupled to the amplifier. The first variable current source is coupled to the first mirror-branch circuit, and configured to generate a first reference current. The second variable current source is coupled to the second mirror-branch circuit, and configured to generate a second reference current. The operational amplifier comprises a first input terminal coupled to the second mirror-branch circuit, a second input terminal coupled to the first mirror-branch circuit, and an output terminal coupled to the amplifier. The amplification circuit has a plurality of gain modes, the first reference current is related to the operation current, and the second reference current is related to the operation current.

Another embodiment provides an amplification circuit comprising an input terminal, an output terminal, a first transistor, a second transistor, a third transistor, a fourth transistor, a first variable current source, a second variable current source, an operational amplifier, and a control circuit. The input terminal is configured to receive an input signal. The output terminal is configured to output an amplified input signal. The first transistor comprises a first terminal configured to receive a first reference current, a second terminal coupled to a first reference voltage terminal, and a control terminal. The second transistor comprises a first terminal, a second terminal coupled to the first reference voltage terminal, and a control terminal coupled to the input terminal and the control terminal of the first transistor. The third transistor comprises a first terminal coupled to the output terminal and configured to receive an operation current, a second terminal coupled to the first terminal of the second transistor, and a control terminal. The fourth transistor comprises a first terminal configured to receive a second reference current, a second terminal, and a control terminal coupled to the control terminal of the third transistor. The first variable current source is configured to generate the first reference current. The second variable current source is coupled to the second terminal of the fourth transistor and configured to generate the second reference current. The operational amplifier comprises a first input terminal coupled to the fourth transistor and the second variable current source, a second input terminal coupled to the first transistor and the first variable current source, and an output terminal coupled to the first transistor and the second transistor. The control circuit is coupled to the first variable current source and the second variable current source. The amplification circuit has a plurality of gain modes. The control circuit controls the first variable current source and the second variable current source so that the first reference current is related to the operation current, and the second reference current is related to the operation current in each of the plurality of gain modes.

### BRIEF DESCRIPTION OF THE DRAWINGS

FIG. 1 illustrates an amplification circuit according to an embodiment.

FIG. 2 illustrates an amplification circuit according to another embodiment.

FIG. 3 illustrates a circuit according to an embodiment.

FIG. 4 illustrates the first switch array of the first variable current source according to an embodiment.

FIG. 5 illustrates the second switch array of the second variable current source according to an embodiment.

FIG. 6 illustrates a case where the first switch array controls the first reference current to have seven stages according to an embodiment.

FIG. 7 illustrates a switch according to embodiments.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In the text, when it mentions two voltages are equal, it means a difference between the two voltages can be smaller than 10% of one of the two voltages.

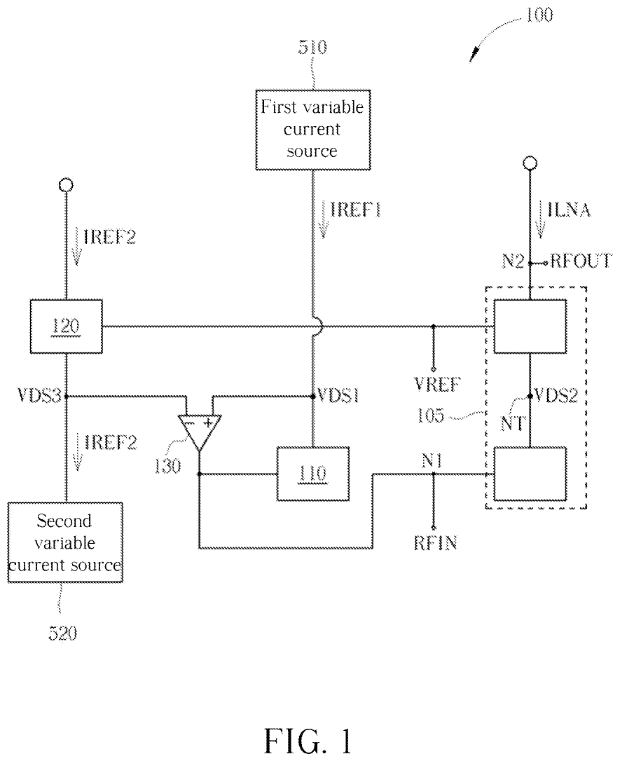

FIG. 1 illustrates an amplification circuit 100 according to an embodiment. The amplification circuit 100 can include an amplifier 105, a first mirror-branch circuit 110, a second mirror-branch circuit 120, a first variable current source 510, a second variable current source 520 and an operational amplifier 130.

The amplifier 105 can receive an operation current ILNA and include a first terminal and a second terminal, where the first terminal can be coupled to an input terminal N1 and receive an input signal RFIN, and the second terminal can be coupled to an output terminal N2 and output an amplified input signal RFOUT. The input signal RFIN can be a radio-frequency (RF) signal, and the output signal RFOUT can be an amplified radio-frequency signal. According to embodiments, the amplifier 105 can be a low-noise amplifier (LNA). The amplifier 105 can further include a bias terminal coupled to a reference voltage terminal VREF having a ground voltage or a predetermined bias voltage.

The first mirror-branch circuit 110 can be coupled to the amplifier 105 and include a transistor. The second mirror-branch circuit 120 can be coupled to the bias terminal of the amplifier 105 and include a transistor.

The first variable current source 510 can be coupled to the first mirror-branch circuit 110 and generate a first reference current IREF1. The second variable current source 520 can be coupled to the second mirror-branch circuit 120 and generate a second reference current IREF2. The first mirror-branch circuit 110 can be driven according to the first reference current IREF1. The second mirror-branch circuit 120 can be driven according to the second reference current IREF2.

The operational amplifier 130 can include a first input terminal, a second input terminal and an output terminal, where the first terminal can be coupled to the second mirror-branch circuit 120, the second input terminal can be coupled to the first mirror-branch circuit 110, and the output terminal can be coupled to the amplifier 105. The operational amplifier 130 can be a differential amplifier, where the first input terminal can be a negative input terminal, and the second input terminal can be a positive input terminal.

The amplification circuit 100 can have a plurality of gain modes. The first reference current IREF1 can be related to the operation current ILNA. The second reference current IREF2 can be related to the operation current ILNA. In different gain modes, the first reference current IREF1, the second reference currents IREF2 and the operation currents ILNA can be changed correspondingly.

In FIG. 1, the first mirror-branch circuit 110 and the first variable current source 510 can form a first current mirror circuit. The second mirror-branch circuit 120 and the second variable current source 520 can form a second current mirror circuit. Hence, the first reference current IREF1 can be mirrored to generate the operation current ILNA. And the second reference current IREF2 can be mirrored to generated the operation current ILNA. The first reference current IREF1 and the operation current ILNA can change synchronously and be positively related to one another. The second reference current IREF2 and the operation current ILNA can change synchronously and be positively related to one another. For example, the operation current ILNA can be K times the first reference current IREF1, and it can be expressed as ILNA=IREF1*K. The operation current ILNA can be K1 times the second reference current IREF2, and it can be expressed as ILNA=IREF2*K1. The parameters K and K1 can be predetermined constants.

As shown in FIG. 1, the amplifier 105 can include a node NT. The second input terminal of the operational amplifier 130 (e.g. connected to a node between the first mirror-branch circuit 110 and the first variable current source 510) can have a first voltage VDS1. The node NT of the amplifier 105 can have a second voltage VDS2. The first input terminal of the operational amplifier 130 (e.g. connected to a node between the second mirror-branch circuit 120 and the second variable current source 520) can have a third voltage VDS3. The first voltage VDS1, the second voltage VDS2 and the third voltage VDS3 can be equal to reduce the impact of changes of transistor bias currents in various process corners of process/voltage/temperature (PVT).

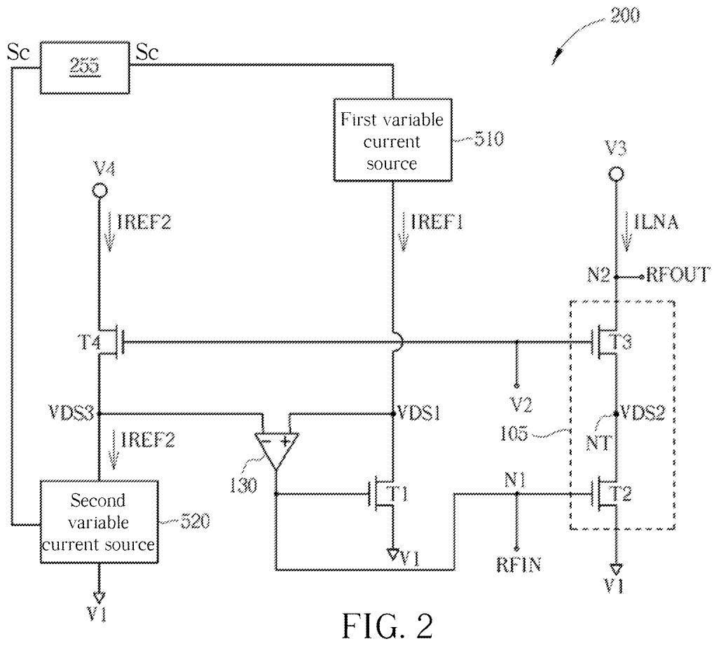

FIG. 2 illustrates an amplification circuit 200 according to another embodiment. The amplification circuit 200 can include the input terminal N1, the output terminal N2, a first transistor T1, a second transistor T2, a third transistor T3, a fourth transistor T4, the first variable current source 510, the second variable current source 520, the operational amplifier 130 and a control circuit 255.

The input terminal N1 of the amplification circuit 200 can receive the input signal RFIN. The output terminal N2 of the amplification circuit 200 can output the amplified input signal RFOUT. The input signal RFIN can be a frequency-radio signal, and the amplified input signal RFOUT can be an amplified frequency-radio signal.

The first transistor T1 can include a first terminal, a second terminal and a control terminal, where the first terminal can receive the first reference current IREF1, and the second terminal can be coupled to a first reference voltage terminal V1. The first reference voltage terminal VI can have a ground voltage or a predetermined bias voltage.

The second transistor T2 can include a first terminal, a second terminal and a control terminal, where the second terminal can be coupled to the first reference voltage terminal V1, and the control terminal can be coupled to the input terminal N1 and the control terminal of the first transistor T1 to receive the input signal RFIN.

The third transistor T3 can include a first terminal, a second terminal and a control terminal. The first terminal of the third transistor T3 can be coupled to the output terminal N2, receive an operation current ILNA through a reference voltage terminal V3, and output the amplified input signal RFOUT. The second terminal of the third transistor T3 can be coupled to the first terminal of the second transistor T2. The control terminal of the third transistor T3 can be coupled to the reference voltage terminal V2, and the reference voltage terminal V2 may be the reference voltage terminal VREF in FIG. 1.

The fourth transistor T4 can include a first terminal, a second terminal and a control terminal, where the first terminal can receive the second reference current IREF2 through a reference voltage terminal V4, the second terminal can be coupled to the second variable current source 520, and the control terminal can be coupled to the control terminal of the third transistor T3.

The first variable current source 510 can generate the first reference current IREF1. The second variable current source 520 can generate the second reference current IREF2. The operational amplifier 130 can include a first input terminal, a second input terminal and an output terminal, where the first input terminal can be coupled to the fourth transistor T4 and the second variable current source 520, the second input terminal can be coupled to the first transistor T1 and the first variable current source 510, and the output terminal can be coupled to the control terminals of the first transistor T1 and the second transistor T2. The operational amplifier 130 can be a differential amplifier, where the first input terminal can be a negative input terminal, and the second input terminal can be a positive input terminal.

The first mirror-branch circuit 110 of FIG. 1 can be formed using the first transistor T1. The second mirror-branch circuit 120 of FIG. 1 can be formed using the fourth transistor T4. The amplifier 105 of FIG. 1 can be formed using the second transistor T2 and the third transistor T3.

The control circuit 255 can be coupled to the first variable current source 510 and the second variable current source 520. The amplification circuit 200 can have a plurality of gain modes. The control circuit 255 can control the first variable current source 510 and the second variable current source 520, so the first reference current IREF1 can be related to the operation current ILNA, and the second reference current IREF2 can be related to the operation current ILNA in each of the plurality of gain modes.

In FIG. 2, the first reference current IREF1 and the operation current ILNA can change synchronously and be positively related to one another. The second reference current IREF2 and the operation current ILNA can change synchronously and be positively related to one another. For example, the operation current ILNA can be K times the first reference current IREF1, and it can be expressed as ILNA=IREF1*K. The operation current ILNA can be K1 times the second reference current IREF2, and it can be expressed as ILNA=IREF2*K1. The parameters K and K1 can be predetermined constants.

In FIG. 2, the width/length ratio (W/L ration) of the second transistor T2 can be K times the width/length ratio of the first transistor T1. Correspondingly, the operation current ILNA can be K times the first reference current IREF1 (i.e. ILNA=IREF1*K). The width/length ratio of the third transistor T3 can be K1 times the width/length ratio of the fourth transistor T4. Correspondingly, the operation current ILNA can be K1 times the second reference current IREF2 (i.e. ILNA=IREF2*K1).

When laying out the transistors, the sizes and the width/length ratios of the transistors can be adjusted so that the operation current ILNA and the first reference current IREF1 have a predetermined ratio, and the operation current ILNA and the second reference current IREF2 have a predetermined ratio.

As shown in FIG. 2, the first input terminal of the operational amplifier 130 can be coupled to the second terminal of the fourth transistor T4. The second input terminal of the operational amplifier 130 can be coupled to the first terminal of the first transistor T1. The output terminal of the operational amplifier 130 can be coupled to the control terminals of the first transistor T1 and the second transistor T2. The second input terminal of the operational amplifier 130 can have the first voltage VDS1. The first terminal of the second transistor T2 can have the second voltage VDS2. The first input terminal of the operational amplifier 130 can have the third voltage VDS3. The first voltage VDS1, the second voltage VDS2 and the third voltage VDS3 can be equal.

In FIG. 2, since the second variable current source 520 is in use, the second terminal of the fourth transistor T4 can have a variable voltage level. For example, in an embodiment of using metal-oxide-semiconductor transistors, the voltage (e.g. the third voltage VDS3) of the second terminal of the fourth transistor T4 (e.g. source terminal) can change with a gate-source voltage of the transistor in the second variable current source 520. Moreover, the first transistor T1 and the second transistor T2 can vary synchronously with the process variation. In other words, the process corner related to the first transistor T1 can be the same as or similar to the process corner related to the second transistor T2, where the process corners can be corresponding to process/voltage/temperature (PVT). The third transistor T3 and the fourth transistor T4 can vary synchronously with the process variation. In other words, the process corner related to the third transistor T3 can be the same as or similar to the process corner related to the fourth transistor T4.

The operational amplifier 130 can have a high input resistance and a low output resistance, so the operational amplifier 130 can be used to fix the voltages of the first terminals (e.g. drain terminals) of the first transistor T1 and the second transistor T2. The voltages of the control terminals (e.g. gate terminals) of the first transistor T1 and the second transistor T2 can be controlled with a feedback operation. When the first reference current IREF1 is outputted to the first transistor T1, the first voltage VDS1 is generated at the first terminal of the first transistor T1. The fourth transistor T4 driven by the second reference current IREF2 can have the third voltage VDS3 at the second terminal (e.g. source terminal) of the fourth transistor T4. The operational amplifier 130 can be used to control the control terminals (e.g. gate terminals) of the first transistor T1 and the second transistor T2. As a result, the voltages of the first terminals of the first transistor T1 and the second transistor T2 can be fixed, so the first voltage VDS1, the second voltage VDS2 and the third voltage VDS3 can be equal (i.e. VDS1=VDS2=VDS3). Since the first voltage VDS1, the second voltage VDS2 and the third voltage VDS3 are maintained equal, the impact of changes of transistor bias currents in various process corners of process/voltage/temperature (PVT) is reduced.

In FIG. 1 and FIG. 2, the first reference current IREF1 can have N stages, the second reference current IREF2 can have M stages, and each of the amplification circuits 100 and 200 can have L gain modes. N, M and L can be integers, N, M and L can be equal (i.e. N=M+L), and each of N, M and L is larger than one. The first reference current IREF1 and the second reference current IREF2 can be adjusted synchronously corresponding to the L gain modes, so the impact of changes of transistor bias currents in various process corners of PVT is reduced when the amplification circuits 100 and 200 are operated in different gain modes.

For example. if M=N=L=7 and K=K1=10, the first reference current IREF1 can be one of 350 microamperes (μA), 450 μA, 550 μA, 600 μA, 650 μA, 700 μA and 750 μA, which are of 7 stages. Similarly, the second reference current IREF2 can be one of 350 μA, 450 μA, 550 μA, 600 μA, 650 μA, 700 μA and 750 μA, which are of 7 stages. The operation current ILNA can be one of 3.5 milliamperes (mA), 4.5 mA, 5.5 mA, 6 mA, 6.5 mA, 7 mA and 7.5 mA, which are of 7 stages. In this example, each of the amplification circuits 100 and 200 can have seven gain modes. However, this is an example, and embodiments are not limited thereto.

In the plurality of gain modes of the amplification circuits 100 and 200, the operation current ILNA can be K times the first reference current IREF1 (i.e. ILNA=IREF1*K), and the operation current ILNA can be K1 times the second reference current IREF2 (i.e. ILNA=IREF2*K1). The parameters K and K1 can be predetermined constants.

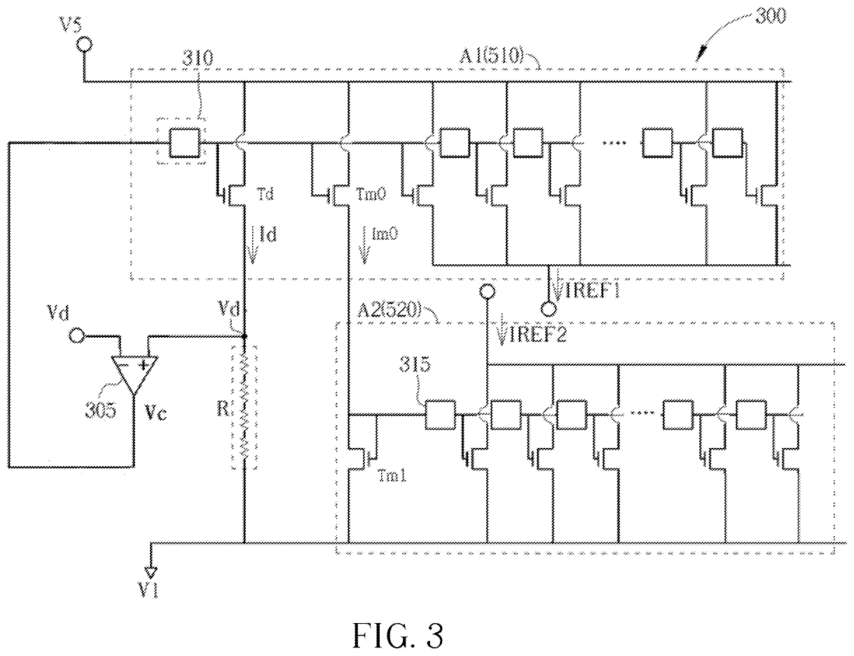

FIG. 3 illustrates a circuit 300 according to an embodiment. The circuit 300 can be a part of the amplification circuit 100 of FIG. 1 or the amplification circuit 200 of FIG. 2. As shown in FIG. 3, the first variable current source 510 can include a first switch array A1, and the second variable current source 520 can include a second switch array A2. The first switch array A1 and the second switch array A2 can be controlled by the control circuit 255 to output the first reference current IREF1 and the second reference current IREF2 respectively.

In FIG. 3, a switch 310 can be a main switch of the first switch array A1 and the second switch array A2. When the switch 310 is turned off, the first reference current IREF1 and the second reference current IREF2 can be close to zero. The switch 315 can be a main switch of the second switch array A2. When the switch 315 is turned off, the second reference current IREF2 can be close to zero. The sub-reference voltage Vd and a resistance unit R can generate a sub-reference current Id, and it can be expressed as Id=Vd/R. The sub-reference current Id (e.g. 200 μA) can be amplified by the current mirror to generate a current (e.g. 350 μA) of the first stage of the first reference current IREF1 and the second reference current IREF2.

The first switch array A1 can further include a sub-reference transistor Td and a sub-reference mirror transistor Tm0. The second switch array A2 can further include a sub-reference mirror transistor Tm1. The sub-reference transistor Td is coupled to and controlled by the switch 310 to output the sub-reference current Id according to the sub-reference voltage Vd. The sub-reference mirror transistor Tm0 is coupled to and controlled by the switch 310. The sub-reference mirror transistor Tm1 is coupled to the sub-reference mirror transistor Tm0 and the switch 315. The sub-reference mirror transistor Tm0 and the sub-reference mirror transistor Tm1 are used to generate a reference mirror current Im0 according to the sub-reference current Id.

The circuit 300 can further include an operational amplifier 305. The operational amplifier 305 can include a first input terminal, a second input terminal and an output terminal. The operational amplifier 305 can be a differential amplifier, where the first input terminal can be a negative input terminal to receiving the voltage Vd, the second input terminal can be a positive input terminal used to fix the sub-reference voltage Vd, and the output terminal can output a control voltage Vc to the switch 310.

A control signal Sc of FIG. 2 can be used to control the first switch array A1 and the second switch array A2. The plurality current values of the first reference current IREF1 and the second reference current IREF2 corresponding to the plurality of stages are described below.

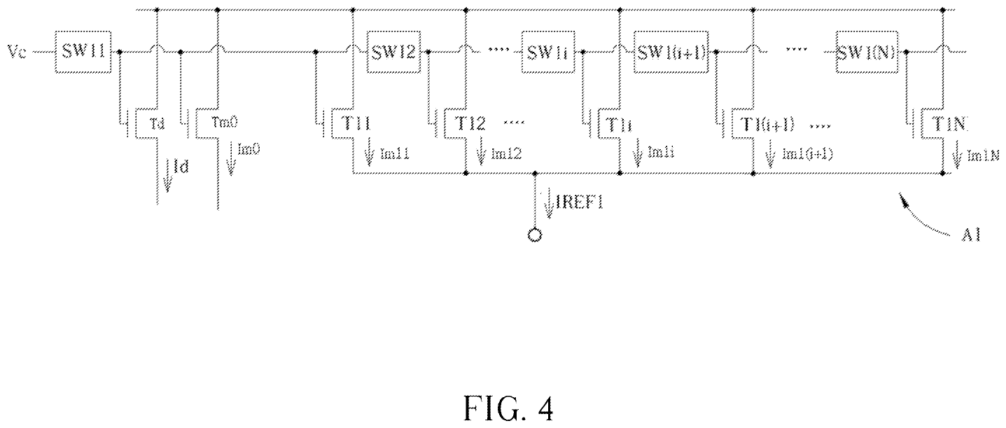

FIG. 4 illustrates the first switch array A1 of the first variable current source 510 according to an embodiment. The first switch array A1 can include a first transistor T11 to an Nth transistor T1N and a first switch SW11 to an Nth switch SW1N. The first switch SW11 can be the switch 310 of FIG. 3. The first transistor T11 to the Nth transistor T1N can be respectively controlled by the first switch SW11 to the Nth switch SW1N to be turned on or turned off to respectively generate a first sub-mirror current Im11 to an Nth sub-mirror current Im1N. The first switch SW11 to the Nth switch SW1N are controlled by the control signal Sc of the control circuit 255. The sum of the first sub-mirror current Im11 to the Nth sub-mirror current Im1N can be the first reference current IREF1.

The first transistor T11 to the Nth transistor T1N each can include a first terminal, a second terminal and a control terminal. The first switch SW11 to the Nth switch SW1N each can include a first terminal and a second terminal. A first terminal of an ith transistor T1i can be coupled to a first terminal of an (i+1)th transistor T1(i+1). A control terminal of the ith transistor T1i can be coupled to a second terminal of an ith switch SW1i. A control terminal of the (i+1)th transistor T1(i+1) can be coupled to a second terminal of an (i+1)th switch SW1(i+1). The second terminal of the ith switch SW1i can be coupled to a first terminal of the (i+1)th switch SW1(i+1). A second terminal of the ith transistor T1i can be coupled to a second terminal of the (i+1)th transistor T1(i+1) and used to output the first reference current IREF1. N and i are integers larger than zero, and i<N.

In FIG. 4, when the first transistor T11 is turned on, the second transistor T12 to the Nth transistor T1N are turned off, and the first transistor T11 is used to generate the first sub-mirror current Im11 according to the sub-reference current Id. The first reference current IREF1 can have a first current value (i.e. the current value of the first sub-mirror current Im11, e.g. 350 μA).

When the first transistor T11 and the second transistor T12 are turned on, the third transistor T13 to the Nth transistor T1N are turned off, and the first transistor T11 and the second transistor T12 are used to generate the first sub-mirror current Im11 and the second sub-mirror current Im12 respectively according to the sub-reference current Id. The first reference current IREF1 can have a second current value (i.e. the sum of the current values of the first sub-mirror current Im11 and the second sub-mirror current Im12, e.g. 450 μA).

Likewise, when the first transistor T11 to the Nth transistor T1N are turned on, the first transistor T11 to the Nth transistor T1N are used to generate the first sub-mirror current Im11 to the Nth sub-mirror current Im1N respectively according to the sub-reference current Id. The first reference current IREF1 can have an Nth current value (i.e. the sum of the current values of the first sub-mirror current Im11 to the Nth sub-mirror current Im1N, e.g. 750 μA).

Hence, the first reference current IREF1 can have N stages, and the first reference current IREF1 can be adjusted to be one of N current values, achieving more precise control.

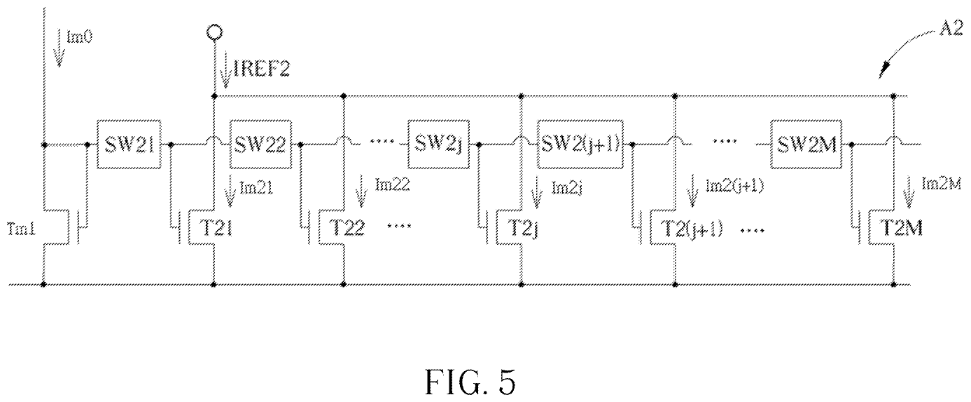

FIG. 5 illustrates the second switch array A2 of the second variable current source 520 according to an embodiment. The second switch array can include a first transistor T21 to an Mth transistor T2M and a first switch SW21 to an Mth switch SW2M. The first switch SW21 can be the switch 315 of FIG. 3. The first transistor T21 to the Mth transistor T2M can be controlled by the first switch SW21 to the Mth switch SW2M to be turned on or turned off respectively to generate a first sub-mirror current Im21 to an Mth sub-mirror current Im2M respectively. The first switch SW21 to the Mth switch SW2M can be controlled by the control signal Sc of the control circuit 255. The sum of the first sub-mirror current Im21 to the Mth sub-mirror current Im2M can be the second reference current IREF2.

The first transistor T21 to the Mth transistor T2M each can include a first terminal, a second terminal and a control terminal. The first switch SW21 to the Mth switch SW2M each can include a first terminal and a second terminal. A first terminal of a jth transistor T2j can be coupled to a first terminal of a (j+1)th transistor T2(j+1). A control terminal of the jth transistor T2j can be coupled to a second terminal of a jth switch SW2j. A second terminal of the jth transistor T2j can be coupled to a second terminal of the (j+1)th transistor T2(j+1) and be used to output the second reference current IREF2. The second terminal of the jth switch SW2j can be coupled to a first terminal of a (j+1)th switch SW2(j+1). M and j are integers larger than zero, and j<M.

In FIG. 5, when the first transistor T21 is turned on, the second transistor T22 to the Mth transistor T2M are turned off, and the first transistor T21 is used to generate the first sub-mirror current Im21 according to the reference mirror current Im0. The second reference current IREF2 can have a first current value (i.e. the current value of the first sub-mirror current Im21, e.g. 350 μA).

When the first transistor T21 and the second transistor T22 are turned on, the third transistor T23 to the Mth transistor TIM are turned off, and the first transistor T21 and the second transistor T22 are used to generate the first sub-mirror current Im21 and the second sub-mirror current Im22 respectively according to the reference mirror current Im0. The second reference current IREF2 can have a second current value (i.e. the sum of the current values of the first sub-mirror current Im21 and the second sub-mirror current Im22, e.g. 450 μA).

Likewise, when the first transistor T21 to the Mth transistor T2M are turned on, the first transistor T21 to the Mth transistor T2M are used to generate the first sub-mirror current Im21 to the Mth sub-mirror current Im1M respectively according to the reference mirror current Im0. The second reference current IREF2 can have an Mth current value (i.e. the sum of the current values of the first sub-mirror current Im21 to the Mth sub-mirror current Im2M, e.g. 750 μA).

Hence, the second reference current IREF2 can have M stages, and the second reference current IREF2 can be adjusted to be one of M current values, achieving more precise control.

In the embodiment, the sub-reference transistor Td, the sub-reference mirror transistor Tm0, and the first transistor T11 to the Nth transistor T1N of the first switch array A1 can be in a matched layout. The sub-reference mirror transistor Tm1 and the first transistor T21 to the Mth transistor T2M of the second switch array A2 can be in a matched layout. For example, in a matched layout, currents can flow through transistors along the same direction.

The first switch array A1 of FIG. 4 and the second switch array A2 of FIG. 5 can be controlled by the control circuit 255, so the first transistor T11 to the Nth transistor T1N of the first switch array A1 and the first transistor T21 to the Mth transistor T2M of the second switch array A2 respectively have the same enabled state or disabled state. For example, one transistor in first switch array A1 and a corresponding one transistor in the second switch array A2 can be turned on or turned off synchronously. The first switch array A1 and the second switch array A2 can be controlled by the control signal generated by the control circuit 255. According to embodiments, the control signal can be a digital signal. For example, the control signal Sc of FIG. 2 can be used to control the first switch array A1 and the second switch array A2. According to another embodiment, a first control signal can be used to control the first switch array A1, and a second control signal can be used to control the second switch array A2, where first control signal and the second control signal can be different.

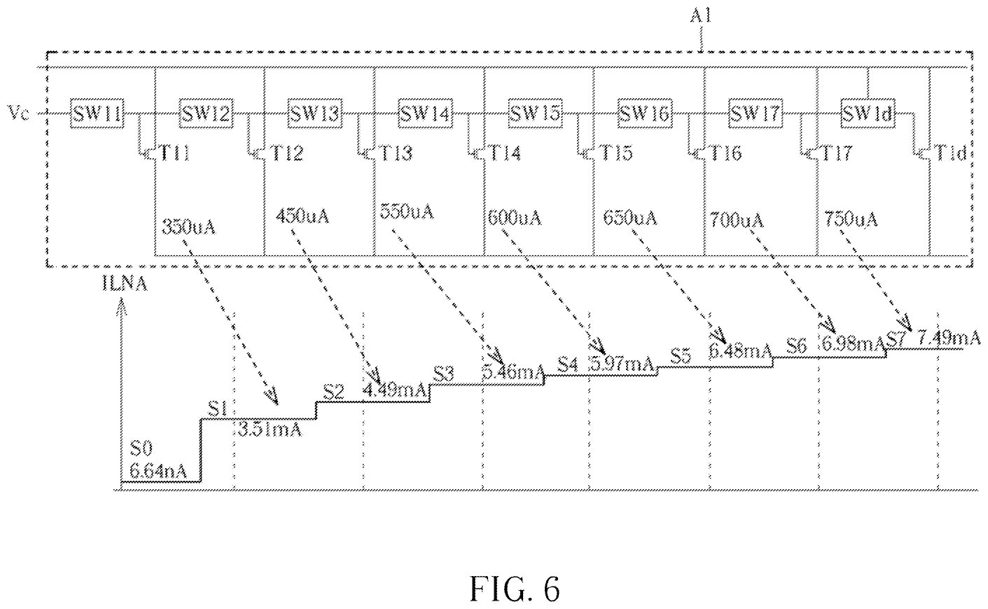

FIG. 6 illustrates a case where the first switch array A1 controls the first reference current IREF1 to have seven stages according to an embodiment. FIG. 6 can be corresponding an embodiment of FIG. 4 where N=7. In FIG. 6, when the first transistor T11 is turned on, the second transistor T12 to the seventh transistor T17 can be turned off, and the first reference current IREF1 can have a first current value (e.g. 350 μA). At this time, the operation current ILNA of FIG. 1 and FIG. 2 can be K times the first current value. For example, K can be 10, and the operation current ILNA can be 3.5 mA.

When the first transistor T11 and the second transistor T12 are turned on, the third transistor T13 to the seventh transistor T17 can be turned off, and the first reference current IREF1 can have a second current value (e.g. 450 μA). At this time, the operation current ILNA of FIG. 1 and FIG. 2 can be K times the first current value. For example, K can be 10, and the operation current ILNA can be 4.5 mA.

When the first transistor T11, the second transistor T12 and the third transistor T13 are turned on, the fourth transistor T14 to the seventh transistor T17 can be turned off, and the first reference current IREF1 can have a third current value (e.g. 550 μA). At this time, the operation current ILNA of FIG. 1 and FIG. 2 can be K times the first current value. For example, K can be 10, and the operation current ILNA can be 5.5 mA.

When the first transistor T11, the second transistor T12, the third transistor T13 and the fourth transistor T14 are turned on, the fifth transistor T15 to the seventh transistor T17 can be turned off, and the first reference current IREF1 can have a fourth current value (e.g. 600 μA). At this time, the operation current ILNA of FIG. 1 and FIG. 2 can be K times the first current value. For example, K can be 10, and the operation current ILNA can be 6 mA.

When the first transistor T11, the second transistor T12, the third transistor T13, the fourth transistor T14 and the fifth transistor T15 are turned on, the sixth transistor T16 and the seventh transistor T17 can be turned off, and the first reference current IREF1 can have a fifth current value (e.g. 650 μA). At this time, the operation current ILNA of FIG. 1 and FIG. 2 can be K times the first current value. For example, K can be 10, and the operation current ILNA can be 6.5 mA.

When the first transistor T11, the second transistor T12, the third transistor T13, the fourth transistor T14, the fifth transistor T15 and the sixth transistor T16 are turned on, the seventh transistor T17 can be turned off, and the first reference current IREF1 can have a sixth current value (e.g. 700 μA). At this time, the operation current ILNA of FIG. 1 and FIG. 2 can be K times the first current value. For example, K can be 10, and the operation current ILNA can be 7 mA.

When the first transistor T11, the second transistor T12, the third transistor T13, the fourth transistor T14, the fifth transistor T15, the sixth transistor T16 and the seventh transistor T17 are turned on, the first reference current IREF1 can have a seventh current value (e.g. 750 μA). At this time, the operation current ILNA of FIG. 1 and FIG. 2 can be K times the first current value. For example, K can be 10, and the operation current ILNA can be 7.5 mA.

In FIG. 6, the switch SW1d and the transistor T1d can be dummy components. The dummy components can be used, unused or omitted optionally. In other words, a dummy switch and/or a dummy transistor can be disposed in each of the first switch array A1 and the second switch array A2 to provide better electronic characteristics.

The abovementioned first switch array A1 and second switch array A2 can be controlled synchronously. For example, when the first switch array A1 generates the first reference current IREF1 of a first stage S1 (e.g. 350 μA), the second switch array A2 can generate the second reference current IREF2 of the first stage S1 (e.g. 350 μA).

When the first switch array A1 generates the first reference current IREF1 of a second stage S2 (e.g. 450 μA), the second switch array A2 can generate the second reference current IREF2 of the second stage S2 (e.g. 450 μA).

When the first switch array A1 generates the first reference current IREF1 of a third stage S3 (e.g. 550 μA), the second switch array A2 can generate the second reference current IREF2 of the third stage S3 (e.g. 550 μA).

Similarly, when the first switch array A1 generates the first reference current IREF1 of a seventh stage S7 (e.g. 750 μA), the second switch array A2 can generate the second reference current IREF2 of the seventh stage S7 (e.g. 750 μA).

In FIG. 6, the evaluated value of the operation current ILNA of the first stage S1 is 3.5 mA, but the actual simulated value is 3.51 mA. The evaluated value of the operation current ILNA of the second stage S2 is 4.5 mA, but the actual simulated value is 4.49 mA. The evaluated value of the operation current ILNA of the third stage S3 is 5.5 mA, but the actual simulated value is 5.46 mA. The evaluated value of the operation current ILNA of the fourth stage S4 is 6.0 mA, but the actual simulated value is 5.97 mA. The evaluated value of the operation current ILNA of the fifth stage S5 is 6.5 mA, but the actual simulated value is 6.48 mA. The evaluated value of the operation current ILNA of the sixth stage S6 is 7.0 mA, but the actual simulated value is 6.98 mA. The evaluated value of the operation current ILNA of the seventh stage S7 is 7.5 mA, but the actual simulated value is 7.49 mA.

In FIG. 6, the errors between the evaluated values and the actual simulated values of the operation current ILNA are all acceptable. Hence, by controlling the first switch array A1 and the second switch array A2, the first reference current IREF1 and the second reference current IREF2 are controlled accurately and synchronously, so the operation current ILNA is controlled accurately.

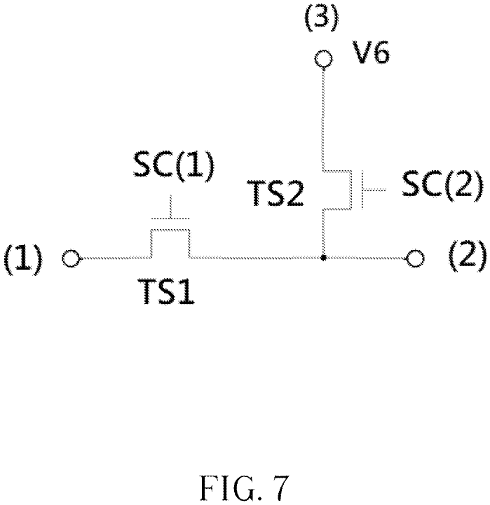

FIG. 7 illustrates a switch according to embodiments. In FIG. 3 to FIG. 5, each switch of the switch 310, the switch 315, the first switch SW11 to the Nth switch SW1N, and the first switch SW21 to the Mth switch SW2M can be like the switch of FIG. 7. The switch of FIG. 7 can include a first terminal (1), a second terminal (2), and a switch transistor TS1 coupled between the first terminal (1) and the second terminal (2). The switch transistor TS1 can be controlled by the control circuit 255. For example, the switch transistor TS1 can be controlled by a first control signal Sc(1) to be turned on or turned off. When the switch transistor TS1 is turned on, the voltages of the first terminal (1) and the second terminal (2) can be equal, and a corresponding transistor of the first transistor T11 to the Nth transistor T1N and the first transistor T21 to the Mth transistor T2M may be turned on. When the switch transistor TS1 is turned off, the voltages of the first terminal (1) and the second terminal (2) can be different, and a corresponding transistor of the first transistor T11 to the Nth transistor T1N and the first transistor T21 to the Mth transistor T2M may be turned off. In an embodiment, the switch of FIG. 7 can further include a third terminal (3) coupled to a reference voltage terminal V6, and a switch transistor TS2 coupled between the second terminal (2) and the third terminal (3). The switch transistors TS1 and TS2 can be controlled by the control circuit 255. For example, the switch transistors TS1 and TS2 can be controlled by the first control signal Sc(1) and a second control signal Sc(2) respectively to be turned on or turned off. When one of the switch transistors TS1 and TS2 is turned on, the other one of the switch transistors TS1 and TS2 can be turned off, so the voltage of the second terminal (2) can be equal to the voltage of the first terminal (1) or the third terminal (3), and a corresponding transistor of the first transistor T11 to the Nth transistor T1N and the first transistor T21 to the Mth transistor T2M may be turned on or turned off. For example, when the switch transistor TS1 is turned on, and the switch transistor TS2 is turned off, the voltages of the first terminal (1) and the second terminal (2) can be equal, and one corresponding transistor of the first transistor T11 to the Nth transistor T1N and the first transistor T21 to the Mth transistor T2M may be turned on. When the switch transistor TS1 is turned off, and the switch transistor TS2 is turned on, the voltages of the second terminal (2) and the third terminal (3) can be equal (e.g. the control voltage Vc), and one corresponding transistor of the first transistor T11 to the Nth transistor T1N and the first transistor T21 to the Mth transistor T2M may be turned off. Taking FIG. 3 and FIG. 4 as an example, when the switch transistor TS1 is turned on and the switch transistor TS2 is turned off, the first terminals (1) and the second terminals (2) of the switch 310 and the first switch SW11 to the Nth switch SW1N can have a voltage of a reference voltage terminal V5 (shown in FIG. 3). When the switch transistor TS2 is turned on and the switch transistor TS1 is turned off, the second terminals (2) of the switch 310 and the first switch SW11 to the Nth switch SW1N can have a voltage of the reference voltage terminal V6.

In summary, by using the amplification circuits 100 and 200, two reference currents synchronously changed with the operation current can be used, so the operation current ILNA can be exactly K times the first reference current IREF1, and the operation current ILNA can be exactly K1 times the second reference current IREF2. Moreover, by using the first switch array A1 and the second switch array A2, each of the first reference current IREF1 and the second reference current IREF2 can be adjusted in a plurality of stages to have a plurality of current values. As a result, stability, accuracy and controllability of the amplification circuits provided by embodiments are effectively improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification circuit, comprising:
an amplifier configured to receive an operation current, and comprising a first terminal configured to receive an input signal, and a second terminal configured to output an amplified input signal;
a first mirror-branch circuit coupled to the amplifier;
a second mirror-branch circuit coupled to the amplifier;
a first variable current source coupled to the first mirror-branch circuit, and configured to generate a first reference current;
a second variable current source coupled to the second mirror-branch circuit, and configured to generate a second reference current; and
an operational amplifier comprising a first input terminal coupled to the second mirror-branch circuit, a second input terminal coupled to the first mirror-branch circuit, and an output terminal coupled to the amplifier;
wherein the amplification circuit has a plurality of gain modes, the first reference current is related to the operation current, and the second reference current is related to the operation current.

2. The amplification circuit of claim 1, wherein the first reference current is positively related to the operation current, and the second reference current is positively related to the operation current.

3. The amplification circuit of claim 1, wherein the amplifier comprises a node, the second input terminal of the operation amplifier has a first voltage, the node of the amplifier has a second voltage, the first terminal of the operation amplifier has a third voltage, and the first voltage, the second voltage and the third voltage are equal.

4. The amplification circuit of claim 1, wherein:
the first variable current source comprises a first switch array;
the second variable current source comprises a second switch array; and
the first switch array and the second switch array are controlled by a control circuit to output the first reference current and the second reference current respectively.

5. An amplification circuit, comprising:
an input terminal configured to receive an input signal;
an output terminal configured to output an amplified input signal;
a first transistor comprising:
a first terminal configured to receive a first reference current;
a second terminal coupled to a first reference voltage terminal; and
a control terminal;
a second transistor comprising:
a first terminal;
a second terminal coupled to the first reference voltage terminal; and
a control terminal coupled to the input terminal and the control terminal of the first transistor;
a third transistor comprising:
a first terminal coupled to the output terminal and configured to receive an operation current;
a second terminal coupled to the first terminal of the second transistor; and
a control terminal;
a fourth transistor comprising:
a first terminal configured to receive a second reference current;
a second terminal; and
a control terminal coupled to the control terminal of the third transistor;
a first variable current source configured to generate the first reference current;
a second variable current source coupled to the second terminal of the fourth transistor and configured to generate the second reference current;
an operational amplifier comprising a first input terminal coupled to the fourth transistor and the second variable current source, a second input terminal coupled to the first transistor and the first variable current source, and an output terminal coupled to the first transistor and the second transistor; and
a control circuit coupled to the first variable current source and the second variable current source;
wherein the amplification circuit has a plurality of gain modes; and
the control circuit controls the first variable current source and the second variable current source so that the first reference current is related to the operation current, and the second reference current is related to the operation current in each of the plurality of gain modes.

6. The amplification circuit of claim 5, wherein the first reference current is positively related to the operation current, and the second reference current is positively related to the operation current.

7. The amplification circuit of claim 5, wherein:
the first input terminal of the operational amplifier is coupled to the second terminal of the fourth transistor;
the second input terminal of the operational amplifier is coupled to the first terminal of the first transistor;
the second input terminal of the operational amplifier has a first voltage;
the first terminal of the second transistor has a second voltage;
the first input terminal of the operational amplifier has a third voltage; and
the first voltage, the second voltage and the third voltage are equal.

8. The amplification circuit of claim 5, wherein:
the first reference current has N stages, the second reference current has M stages, and the amplification circuit has L gain modes; and
N, M and L are integers, N, M and L are equal, and each of N, M and Lis larger than one.

9. The amplification circuit of claim 8, wherein the first reference current and the second reference current are adjusted corresponding to the plurality of gain modes.

10. The amplification circuit of claim 8, wherein in each gain mode of the L gain modes, the operation current is K times the first reference current, the operation current is K1 times the second reference current, and K and K1 are constant values.

11. The amplification circuit of claim 5, wherein the amplification circuit has a first gain mode and a second gain mode, in the first gain mode and the second gain mode, the operation current is K times the first reference current, the operation current is K1 times the second reference current, and K and K1 are constants.

12. The amplification circuit of claim 5, wherein:
the first variable current source comprises a first switch array;
the second variable current source comprises a second switch array; and
the first switch array and the second switch array are controlled by the control circuit to generate the first reference current and the second reference current respectively.

13. The amplification circuit of claim 12, wherein:
the first switch array comprises a first transistor to an Nth transistor and a first switch to an Nth switch;
the first transistor to the Nth transistor of the first switch array are controlled by the first switch to the Nth switch of the first switch array to be turned on or turned off respectively to generate a first sub-mirror current to an Nth sub-mirror current of the first switch array respectively;
the first switch to the Nth switch of the first switch array are controlled by the control circuit; and
N is an integer larger than one.

14. The amplification circuit of claim 13, wherein:
the first transistor to the Nth transistor of the first switch array each comprise a first terminal, a second terminal and a control terminal;
the first switch to the Nth switch of the first switch array each comprise a first terminal and a second terminal;
a first terminal of an ith transistor is coupled to a first terminal of an (i+1)th transistor in the first switch array;
a control terminal of the ith transistor is coupled to a second terminal of an ith switch in the first switch array;
a second terminal of the ith transistor is coupled to a second terminal of the (i+1)th transistor in the first switch array;
a second terminal of the ith switch is coupled to a first terminal of a (i+1)th switch in the first switch array; and
N and i are integers larger than one, and i<N.

15. The amplification circuit of claim 13, wherein:
the second switch array comprises a first transistor to an Mth transistor and a first switch to an Mth switch;
the first transistor to the Mth transistor of the second switch array are controlled by the first switch to the Mth switch of the second switch array to be turned on or turned off respectively to generate a first sub-mirror current to an Mth sub-mirror current of the second switch array respectively;
the first switch to the Mth switch of the second switch array are controlled by the control circuit; and
M is an integer larger than one.

16. The amplification circuit of claim 15, wherein:
the first transistor to the Mth transistor of the second switch array each comprise a first terminal, a second terminal and a control terminal;
the first switch to the Mth switch of the second switch array each comprise a first terminal and a second terminal;
a first terminal of a jth transistor is coupled to a first terminal of a (j+1)th transistor in the second switch array;
a control terminal of the jth transistor is coupled to a second terminal of a jth switch in the second switch array;
a second terminal of the jth transistor is coupled to a second terminal of the (j+1)th transistor in the second switch array;
a second terminal of the jth switch is coupled to a first terminal of a (j+1)th switch in the second switch array; and
M and j are integers larger than 1, and j<M.

17. The amplification circuit of claim 15, wherein the first transistor to the Nth transistor of the first switch array and the first transistor to the Mth transistor of the second switch array respectively have a same enabled state or disabled state.

18. The amplification circuit of claim 15, wherein each switch of the first switch to the Nth switch of the first switch array and the first switch to the Mth switch of the second switch array comprises:
a first terminal;
a second terminal;
a third terminal coupled to a second reference voltage terminal;
a first switch transistor coupled between the first terminal and the second terminal of the each switch; and
a second switch transistor coupled between the second terminal and the third terminal of the each switch;
wherein the first switch transistor and the second switch transistor are controlled by the control circuit;
when the first switch transistor is in one of an ON state and an OFF state, the second switch transistor is in another one of the ON state and the OFF state.

19. The amplification circuit of claim 15, wherein:
the first switch array further comprises:
a sub-reference transistor coupled to the first switch of the first switch array and configured to output a sub-reference current according to a sub-reference voltage; and
a first sub-reference mirror transistor coupled to the first switch of the first switch array and configured to output a first reference mirror current according to the sub-reference current;
wherein the first transistor to the Nth transistor of the first switch array generate the first sub-mirror current to the Nth sub-mirror current of the first switch array respectively according to the sub-reference current; and
the second switch array further comprises:
a second sub-reference mirror transistor coupled between the first sub-reference mirror transistor and the first transistor of the second switch array and configured to receive the first reference mirror current;
wherein the first transistor to the Mth transistor of the second switch array generate the first sub-mirror current to the Mth sub-mirror current of the second switch array respectively according to the first reference mirror current.

20. The amplification circuit of claim 19, wherein:
the sub-reference transistor, the first sub-reference mirror transistor and the first transistor to the Nth transistor of the first switch array are in a matched layout; and
the second sub-reference mirror transistor and the first transistor to the Mth transistor of the second switch array are in a matched layout.
